(19) United States
(12) Patent Application Publication
(10) Pub. No.: US 2021/0184180 A1
(43) Pub. Date: Jun. 17, 2021

(54) MANUFACTURING METHOD OF OLED PANEL AND OLED PANEL

(71) Applicant: WUHAN CHINA STAR OPTOELECTRONICS SEMICONDUCTOR DISPLAY TECHNOLOGY CO., LTD., Wuhan (CN)

(72) Inventors: Ming ZHANG, Wuhan (CN); Jie YANG, Wuhan (CN); Hsianglun HSU, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/320,107

(22) PCT Filed: Jan. 4, 2019
(86) PCT No.: PCT/CN2019/070454

§ 371 Date: Jan. 24, 2019

(30) Foreign Application Priority Data
Dec. 14, 2018 (CN) 201811537015.6

(51) Int. Cl. H01L 51/56; H01L 51/52; H01L 27/32

(52) U.S. Cl. CPC H01L 51/56; H01L 51/5253; H01L 51/5209; H01L 2251/558; H01L 27/3262; H01L 27/3246; H01L 51/5225

(57) ABSTRACT

A manufacturing method of an OLED panel and an OLED panel are provided. The manufacturing method of an OLED panel includes: providing a TFT substrate; coating, by evaporation, a PLN layer, an anode, a PDL layer, and an EL layer on the TFT substrate sequentially; forming a first cathode on the PDL layer and the EL layer; and forming a second cathode on the first cathode corresponding to the PDL layer. The manufacturing method reduces the transverse electrical resistance of the cathode of the OLED effectively and reduces the thermal effect of OLED panel to improve the display effect of OLED panel.

### FIELD OF INVENTION

The present disclosure relates to the field of display technologies, and more particularly to a manufacturing method of an OLED panel and the OLED panel.

### BACKGROUND OF INVENTION

Organic light emitting diode (OLED) has many advantages, for example, spontaneous light emission, high contrast, wide viewing angle, low power consumption and easily-bendable, and therefore, is loved by the public and designers. Flexible OLED displays are gradually taking over the market due to their flexible and thin characteristics. The OLED panel mainly includes a display area and a non-display area. Thin film transistor (TFT) wirings used for driving pixels are within the display area. And, a variety of metal wirings, which are connected to cathodes, anodes and gate electrodes, source electrodes and drain electrodes of TFTs of the OLED panel, are distributed in non-display area.

Nowadays, most of the OLEDs are top-emitting type. In addition to high opening rate, it also has the advantages of high color purity and high efficiency. OLED is a current driving element, and each pixel includes a separate anode and a common cathode. For the top-emitting OLED structure, in order to utilize the micro-cavity effect effectively, the anode is a total reflection electrode and the cathode is a semi-reflection and semi-transmissive electrode. Because the cathode is a common electrode and in order to match the microcavity, the thickness of the cathode film is relatively thin, which is about a dozen of nanometers (nm), and the electrical resistance of the cathode in a transverse direction is larger. The ultra-thin common cathode structure makes the voltage distribution loaded on OLED panel uneven due to different locations of different pixels relative to the power supply. That is, the pixels which are located close to the power supply have a low voltage and a low thermal effect, while the pixels which are located far away from the power supply have a high voltage and a high thermal effect. As a result, the thermal effect of the whole OLED panel is uneven, which leads to different degrees of OLED degradation and affects the display effect.

In addition, the OLED panel is designed with a narrow border in order to give the flexible advantage of the OLED panel a full play, and the cathode signal is no longer input from the bottom of the panel, but from the left and right sides of the panel. Such design also causes the problem of thermal effect due to voltage drop of the cathode.

### SUMMARY OF INVENTION

An object of the present disclosure is to provide a manufacturing method of an OLED panel and the OLED panel to solve the problem of thermal effect caused by large electrical resistance of the cathode in a transverse direction in existing OLED panels.

To achieve the above object, an embodiment of the present disclosure provides a manufacturing method of an OLED panel. The manufacturing method of an OLED panel includes:

providing a TFT substrate;

coating, by evaporation, a planarization (PLN) layer, an anode, a pixel defining layer (PDL), and an electroluminescence (EL) layer on the TFT substrate sequentially;

forming a first cathode on the PDL layer and the EL layer; and

forming a second cathode on the first cathode corresponding to the PDL layer.

Further, forming a first cathode on the PDL layer and the EL layer includes the following step:

coating, by evaporation, the first cathode on the PDL layer and the EL layer by using an open mask, and a thickness of the first cathode matches a thickness of a microcavity film of the OLED panel.

Further, forming a second cathode on the first cathode corresponding to the PDL layer includes the following step:

coating, by evaporation, the second cathode on the first cathode corresponding to the PDL layer by using a pattern mask.

Further, a thickness of the second cathode is more than 50 nm.

Further, forming a second cathode on the first cathode corresponding to the PDL layer includes the following step:

forming a plurality of electrodes on the first cathode corresponding to the PDL layer which are used as the second cathode, and the electrodes are arranged in a straight line or a curved line.

Further, a plurality of open areas arranged in an array are disposed on the PDL layer, and the EL layer is within the plurality of open areas; the plurality of electrodes are arranged in parallel, and at least two rows of the open areas are located between two adjacent electrodes, a width of each electrode is less than or equal to a half of a spacing between two adjacent rows of the open areas.

Accordingly, an embodiment of the present disclosure provides an OLED panel, the OLED panel includes:

a TFT substrate;

a PLN layer, an anode, a PDL layer, and an EL layer coated, by evaporation, on the TFT substrate sequentially;

a first cathode formed on the PDL layer and the EL layer; and

a second cathode formed on the first cathode corresponding to the PDL layer.

Further, a thickness of the first cathode matches a thickness of a microcavity film of the OLED panel, and a thickness of the second cathode is more than 50 nm.

Further, the second cathode includes a plurality of electrodes, and each electrode is arranged in a straight line or a curved line.

Further, a plurality of open areas arranged in an array are disposed on the PDL layer, and the EL layer is within the plurality of open areas; the plurality of electrodes are arranged in parallel, and at least two rows of the open areas are located between two adjacent electrodes, a width of each electrode is less than or equal to a half of a spacing between two adjacent rows of the open areas.

Accordingly, an embodiment of the present disclosure also provides an OLED panel, the OLED panel includes:

a TFT substrate;

a PLN layer, an anode, a PDL layer, and an EL layer coated, by evaporation, on the TFT substrate sequentially;

a first cathode formed on the PDL layer and the EL layer;

a second cathode formed on the first cathode corresponding to the PDL layer, and a thickness of the second cathode is more than 50 nm.

Further, a thickness of the first cathode matches a thickness of a microcavity film of the OLED panel.

Further, the second cathode includes a plurality of electrodes, and each electrode is arranged in a straight line or a curved line.

Further, a plurality of open areas arranged in an array are disposed on the PDL layer, and the EL layer is within the plurality of open areas; the plurality of electrodes are arranged in parallel, and at least two rows of the open areas are spaced between two adjacent electrodes, a width of each electrode is less than or equal to a half of a spacing between two adjacent rows of the open areas.

The benefits of the present invention are: a first cathode is formed on the PDL layer and the EL layer after coating, by evaporation, a PLN layer, an anode, a PDL, and an EL layer on the TFT substrate sequentially, and then a second cathode is formed on the first cathode corresponding to the PDL layer to thicken the cathode on the PDL layer, which reduces the transverse electrical resistance of the cathode of the OLED effectively and reduces the thermal effect of OLED panel to improve the display effect of OLED panel.

### DESCRIPTION OF DRAWINGS

According to the detailed description of the specific embodiment of the present disclosure combined with of the accompanying figures, the technical solution and other beneficial effects of the present disclosure will be obvious.

FIG. 1 is a flow diagram of a manufacturing method of an OLED panel according to an embodiment of the present disclosure.

FIG. 2 is a partial structural diagram of an OLED panel according to an embodiment of the present disclosure.

FIG. 3 is a partial structural diagram of another OLED panel according to an embodiment of the present disclosure.

FIG. 4 is a structural diagram of an OLED panel according to an embodiment of the present disclosure.

FIG. 5 is another structural diagram of an OLED panel according to an embodiment of the present disclosure.

FIG. 6 is a position diagram of a PDL and a second cathode of an OLED panel according to an embodiment of the present disclosure.

FIG. 7 is another position diagram of a PDL and a second cathode of an OLED panel according to an embodiment of the present disclosure.

### DETAILED DESCRIPTION OF PREFERRED EMBODIMENTS

A clearly and completely description of the technical solution will be given in combination with the accompanying figures in the embodiment of the present disclosure. It is evident that the embodiments described are only a part of embodiments of the present disclosure and not all of them. Based on the embodiment of the present disclosure, all other embodiments obtained by person skilled in the art without making any invention efforts all belong to the scope of protection in the present disclosure.

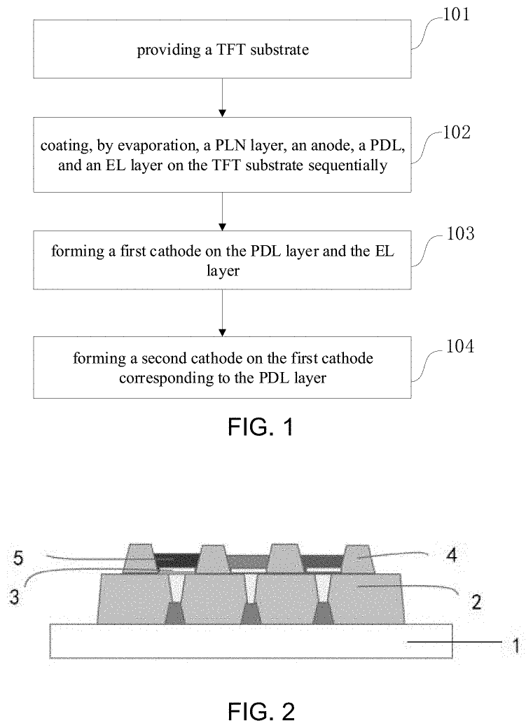

As shown in FIG. 1, FIG. 1 is a flow diagram of a manufacturing method of an OLED panel according to an embodiment of the present disclosure. The manufacturing method includes the following steps:

Step 101, providing a TFT substrate.

As shown in FIG. 2, a clean TFT substrate 1 is provided.

Step 102, coating, by evaporation, a PLN layer, an anode, a PDL, and an EL layer on the TFT substrate sequentially.

As shown in FIG. 2, a PLN layer (a planarization layer) 2, an anode 3, a PDL (a pixel defining layer) layer 4, and an EL layer 5 are coated, by evaporation, on the TFT substrate 1 sequentially. The PLN layer 2 is formed on the TFT substrate 1, the anode 3 is formed on the PLN layer 2, the PDL layer 4 is formed on the PLN layer 2, and there is a partial overlap between the PDL layer 4 and the anode 3. A plurality of open areas arranged in an array are disposed on the PDL layer 4, and each open area is wide at the top and narrow at the bottom to expose the anode 3. The EL layer 5 includes a common layer and a luminous layer. The luminous layer is formed on the anode 3 in an area with a plurality of openings, and the common layer is formed on the PDL layer 4 and the anode 3 in an area with a plurality of openings. In a specific embodiment of the present disclosure, a PLN layer 2, an anode 3, a PDL layer 4, and an EL layer 5 are coated, by evaporation, on the TFT substrate 1 sequentially using an open mask.

Step 103, forming a first cathode on the PDL layer and the EL layer.

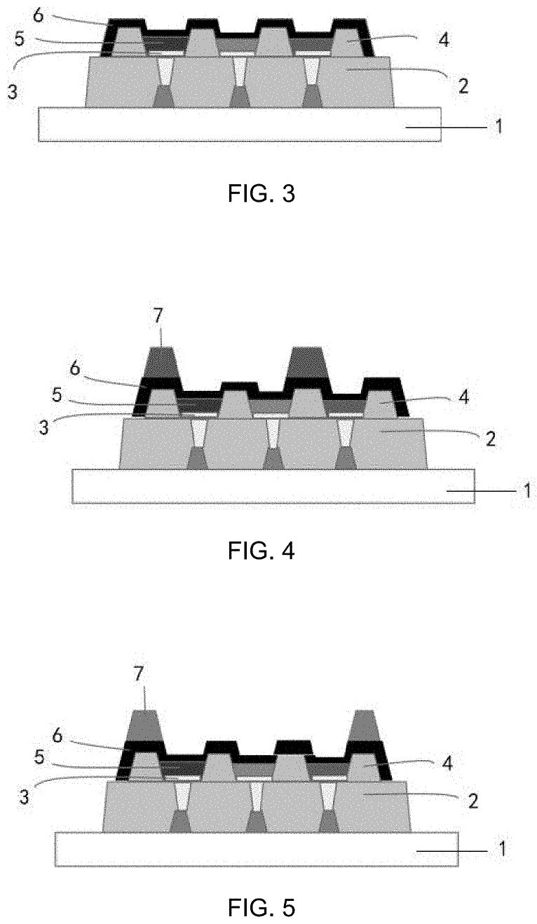

As shown in FIG. 3, a first cathode 6 is formed on the PDL layer 4 and the EL layer 5.

Specifically, the step 103 includes:

coating, by evaporation, the first cathode on the PDL layer and the EL layer by using an open mask, and a thickness of the first cathode matches a thickness of a microcavity film of the OLED panel.

It is understood that, the first cathode 6 is prepared using an open mask. And a thickness of the first cathode 6 is not specified, as long as it can meet the microcavity effect of OLED panel. That is, the thickness of the first cathode 6 matches the thickness of a microcavity film of the OLED panel. In a specific embodiment of the present disclosure, a range of the thickness of the first cathode 6 is about 50-200 nm to meet the semi-reflection and semi-transmissive characteristics of the first cathode 6.

Step 104, forming a second cathode on the first cathode corresponding to the PDL layer.

In an embodiment of the present disclosure, as shown in FIG. 4 or FIG. 5, the second cathode 7 can be formed on an entirety of the first cathode 6 corresponding to the PDL layer 4, and can also be formed on a part of the first cathode 6 corresponding to the PDL layer 4. The material of the second cathode 7 may be the same as or different from the material of the first cathode 6. The thickness of the second cathode 7 is much greater than the thickness of the first cathode 6 to reduce the voltage drop of the cathode in a transverse direction. In a specific embodiment of the present disclosure, the thickness of the second cathode 7 is more than 50 nm.

Specifically, the step 104 includes:

coating, by evaporation, the second cathode on the first cathode corresponding to the PDL layer by using a pattern mask.

It is understood that, the second cathode 7 is prepared using a pattern mask. In addition, the second cathode 7 can also be formed on the first cathode 6 corresponding to the PDL layer 4 by other preparation methods, such as pulsed laser deposition (PLD).

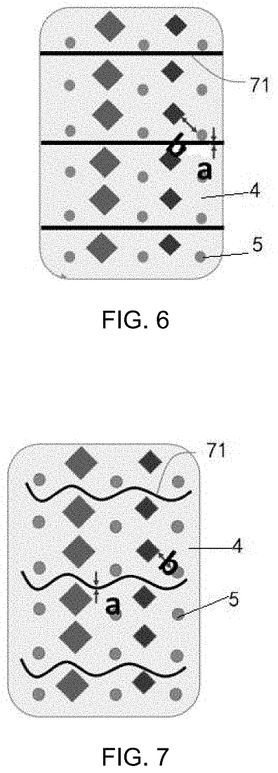

Specifically, the pattern mask is designed when the second cathode 7 is made to adapt to the narrow frame design of the OLED panel; that is, a plurality of open areas are defined in the pattern mask, and correspond to the location of the PDL layer 4. The open areas of the pattern mask are arranged along a direction which is parallel to the down border of the OLED panel, and there is no specific restriction for the shape of the down border, which can be a straight line or a curved line. A spacing between two neighboring openings of the pattern mask is greater than or equal to two times of the PDL gap, and a width of an opening of the pattern mask is less than or equal to a half of a PDL gap. As shown in FIG. 6 or FIG. 7, the PDL gap is the width b of a PDL between two adjacent pixels.

As shown in FIG. 6 or FIG. 7, the second cathode 7 prepared by the pattern mask includes a plurality of electrodes 71. That is, during fabrication, a plurality of electrodes 71 are formed on the first cathode 6 corresponding to the PDL layer 4 which are used as the second cathode 6. In a specific embodiment of the present disclosure, the electrodes 71 can be arranged in a straight line as shown in FIG. 6, and the straight electrodes are parallel to the down border of the OLED panel. The electrodes 71 can also be arranged in a curved line as shown in FIG. 7, and the curved electrodes are extended along a direction which is parallel to the down border of the OLED panel.

In a specific embodiment of the present disclosure, as shown in FIG. 6 or FIG. 7, the electrodes are arranged in parallel with each other. And at least two rows of the open areas are located between two adjacent electrodes 71, that is, the spacing between two adjacent electrodes 71 is greater than or equal to two times of the PDL gap. The width a of each electrode is less than or equal to a half of a spacing between two neighboring openings, that is, the width a of each electrode is less than or equal to a half of a PDL gap.

It is known from the above, for a manufacturing method of an OLED panel according to an embodiment of the present disclosure, a first cathode 6 is formed on the PDL layer 4 and the EL layer 5 after coating, by evaporation, a PLN layer 2, an anode 3, a PDL layer 4, and an EL layer 5 on the TFT substrate 1 sequentially, and then a second cathode 7 is formed on the first cathode 6 corresponding to the PDL layer 4 to thicken the cathode on the PDL layer 4, which reduces the transverse electrical resistance of the cathode of the OLED effectively and reduces the thermal effect of OLED panel to improve the display effect of OLED panel.

As shown in FIG. 4, FIG. 4 is a structural diagram of an OLED panel according to an embodiment of the present disclosure. The OLED panel includes a TFT substrate 1, a PLN layer 2, an anode 3, a PDL layer 4, an EL layer 5, a first cathode 6 and a second cathode 7. The PLN layer 2 is formed on the TFT substrate 1, the anode 3 is formed on the PLN layer 2, the PDL layer 4 is formed on the PLN layer 2. And there is a partial overlap between the PDL layer 4 and the anode 3. A plurality of open areas arranged in an array are disposed on the PDL layer 4, and each open area is wide at the top and narrow at the bottom to expose the anode 3. The EL layer 5 includes a common layer and a luminous layer. The luminous layer is formed on the anode 3 in an area with a plurality of openings, and the common layer is formed on the PDL layer 4 and the anode 3 in an area with a plurality of openings.

The first cathode 6 is formed on the PDL layer 4 and the EL layer 5. A thickness of the first cathode 6 is not specified, as long as it can meet the microcavity effect of OLED panel. That is, the thickness of the first cathode 6 matches the thickness of a microcavity film of the OLED panel. In a specific embodiment of the present disclosure, a range of the thickness of the first cathode 6 is about 50 nm to 200 nm to meet the semi-reflection and semi-transmissive characteristics of the first cathode 6.

The second cathode 7 is formed on the first cathode 6 corresponding to the PDL layer 4. It is understood that, the second cathode 7 can be formed on an entirety of the first cathode 6 corresponding to the PDL layer 4, and can also be formed on a part of the first cathode 6 corresponding to the PDL layer 4 as shown in FIG. 4 or FIG. 5. The material of the second cathode 7 may be the same as or different from the material of the first cathode 6. The thickness of the second cathode 7 is much greater than the thickness of the first cathode 6 to reduce the voltage drop of the cathode in a transverse direction. In a specific embodiment of the present disclosure, the thickness of the second cathode 7 is more than 50 nm.

Further, the second cathode 7 includes a plurality of electrodes 71. The electrodes 71 can be arranged in a straight line as shown in FIG. 6, and the straight electrodes are parallel to the down border of the OLED panel. The electrodes 71 can also be arranged in a curved line as shown in FIG. 7, and the curved electrodes are extended along a direction which is parallel to the down border of the OLED panel.

In a specific embodiment of the present disclosure, as shown in FIG. 6 or FIG. 7, the electrodes 71 are arranged in parallel with each other. And at least two rows of the open areas are located between two adjacent electrodes 71, that is, the spacing between two adjacent electrodes 71 is greater than or equal to two times of the PDL gap. The width a of each electrode is less than or equal to a half of a spacing between two neighboring openings, that is, the width a of each electrode is less than or equal to a half of a PDL gap.

It is known from the above, for an OLED panel according to an embodiment of the present disclosure, a first cathode 6 is formed on the PDL layer 4 and the EL layer 5 after coating, by evaporation, a PLN layer 2, an anode 3, a PDL layer 4, and an EL layer 5 on the TFT substrate 1 sequentially, and then a second cathode 7 is formed on the first cathode 6 corresponding to the PDL layer 4 to thicken the cathode on the PDL layer 4, which reduces the transverse electrical resistance of the cathode of the OLED effectively and reduces the thermal effect of OLED panel to improve the display effect of OLED panel.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A manufacturing method of an organic light emitting diode (OLED) panel, comprising:
providing a thin film transistor (TFT) substrate;
coating, by evaporation, a planarization (PLN) layer, an anode, a pixel defining layer (PDL), and an electroluminescence (EL) layer on the TFT substrate sequentially;
forming a first cathode on the PDL layer and the EL layer; and
forming a second cathode on the first cathode corresponding to the PDL layer.

2. The manufacturing method of the OLED panel according to claim 1, wherein forming a first cathode on the PDL layer and the EL layer comprises the following step:
coating, by evaporation, the first cathode on the PDL layer and the EL layer by using an open mask, and a thickness of the first cathode matches a thickness of a microcavity film of the OLED panel.

3. The manufacturing method of the OLED panel according to claim 1, wherein forming a second cathode on the first cathode corresponding to the PDL layer comprises the following step:
coating, by evaporation, the second cathode on the first cathode corresponding to the PDL layer by using a pattern mask.

4. The manufacturing method of the OLED panel according to claim 1, wherein a thickness of the second cathode is more than 50 nm.

5. The manufacturing method of the OLED panel according to claim 1, wherein forming a second cathode on the first cathode corresponding to the PDL layer comprises the following step:
forming a plurality of electrodes on the first cathode corresponding to the PDL layer which are used as the second cathode, and the electrodes are arranged in a straight line or a curved line.

6. The manufacturing method of the OLED panel according to claim 5, wherein a plurality of open areas arranged in an array are disposed on the PDL layer, and the EL layer is within the plurality of open areas;
the plurality of electrodes are arranged in parallel, and at least two rows of the open areas are located between two adjacent electrodes, a width of each electrode is less than or equal to a half of a spacing between two adjacent rows of the open areas.

7. An OLED panel, comprising:
a TFT substrate;
a PLN layer, an anode, a PDL layer, and an EL layer coated, by evaporation, on the TFT substrate sequentially;
a first cathode formed on the PDL layer and the EL layer; and
a second cathode formed on the first cathode corresponding to the PDL layer.

8. The OLED panel according to claim 7, wherein a thickness of the first cathode matches a thickness of a microcavity film of the OLED panel.

9. The OLED panel according to claim 7, wherein the second cathode comprises a plurality of electrodes, and each electrode is arranged in a straight line or a curved line.

10. The OLED panel according to claim 9, wherein a plurality of open areas arranged in an array are disposed on the PDL layer, and the EL layer is within the plurality of open areas; the plurality of electrodes are arranged in parallel, and at least two rows of the open areas are located between two adjacent electrodes, a width of each electrode is less than or equal to a half of a spacing between two adjacent rows of the open areas.

11. An OLED panel, comprising:
a TFT substrate;
a PLN layer, an anode, a PDL layer, and an EL layer coated, by evaporation, on the TFT substrate sequentially;
a first cathode formed on the PDL layer and the EL layer;
a second cathode formed on the first cathode corresponding to the PDL layer, and a thickness of the second cathode is more than 50 nm.

12. The OLED panel according to claim 11, wherein a thickness of the first cathode matches a thickness of a microcavity film of the OLED panel.

13. The OLED panel according to claim 11, wherein the second cathode comprises a plurality of electrodes, and each electrode is arranged in a straight line or a curved line.

14. The OLED panel according to claim 13, wherein a plurality of open areas arranged in an array are disposed on the PDL layer, and the EL layer is within the plurality of open areas; the plurality of electrodes are arranged in parallel, and at least two rows of the open areas are spaced between two adjacent electrodes, a width of each electrode is less than or equal to a half of a spacing between two adjacent rows of the open areas.
